(19) United States
(12) Patent Application Publication
(10) Pub. No.: US 2026/0083029 A1
(43) Pub. Date: Mar. 19, 2026

(54) SEMICONDUCTOR PACKAGE AND METHOD FOR FORMING THE SAME

(71) Applicant: JCET STATS ChipPAC Korea Limited, Incheon (KR)

(72) Inventors: YeoJun YUN, Incheon (KR); SeungHyun LEE, Incheon (KR); MinSung LEE, Incheon (KR); HeeSoo LEE, Incheon (KR)

(21) Appl. No.: 19/322,703

(22) Filed: Sep. 9, 2025

(30) Foreign Application Priority Data
Sep. 14, 2024 (CN) 202411290176.5

(51) Int. Cl. H01L 23/498; H01L 23/538; H01L 25/00

(52) U.S. Cl. CPC H10W 90/701; H10W 70/614; H10W 90/00

(57) ABSTRACT

A semiconductor package and a method for forming the same are provided. The method includes: providing a first substrate having a first front surface and a first back surface; mounting a plurality of conductive blocks on the first front surface of the first substrate via a first plurality of solder bumps; providing a second substrate having a second front surface and a second back surface; disposing the second substrate on the plurality of conductive blocks via a second plurality of solder bumps, wherein the second front surface of the second substrate faces the first front surface of the first substrate; pressing the first substrate and the second substrate towards each other; and irradiating the first plurality of solder bumps and the second plurality of solder bumps from the first back surface of the first substrate and the second back surface of the second substrate, respectively.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, semiconductor packages are fabricated into smaller sizes to bring about higher density of electronic components. Typically, the semiconductor packages may include key functional modules such as semiconductor chips, and interconnection structures. However, it is noted that certain interconnection formation processes, such as bonding multiple interconnection structures between two substrates, may be complicated. Also, such complicated process may adversely affect the yield of the semiconductor packages incorporating such interconnection structures.

Therefore, a need exists for a method for forming a semiconductor package with an improved yield.

### SUMMARY OF THE INVENTION

An objective of the present application is to provide a method for forming a semiconductor package with an improved yield.

According to an aspect of the present application, a method for forming a semiconductor package is provided. The method may include: providing a first substrate having a first front surface and a first back surface; mounting a plurality of conductive blocks on the first front surface of the first substrate via a first plurality of solder bumps; providing a second substrate having a second front surface and a second back surface; disposing the second substrate on the plurality of conductive blocks via a second plurality of solder bumps, wherein the second front surface of the second substrate faces the first front surface of the first substrate; pressing the first substrate and the second substrate towards each other; and irradiating the first plurality of solder bumps and the second plurality of solder bumps from the first back surface of the first substrate and the second back surface of the second substrate, respectively.

According to another aspect of the present application, a semiconductor package is provided. The semiconductor package may be formed using the above method.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a semiconductor package.

FIGS. 2A to 2F are cross-sectional views illustrating various steps of a method for forming a semiconductor package according to an embodiment of the present application.

FIGS. 3A to 3F are cross-sectional views illustrating various steps of a method for forming a semiconductor package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

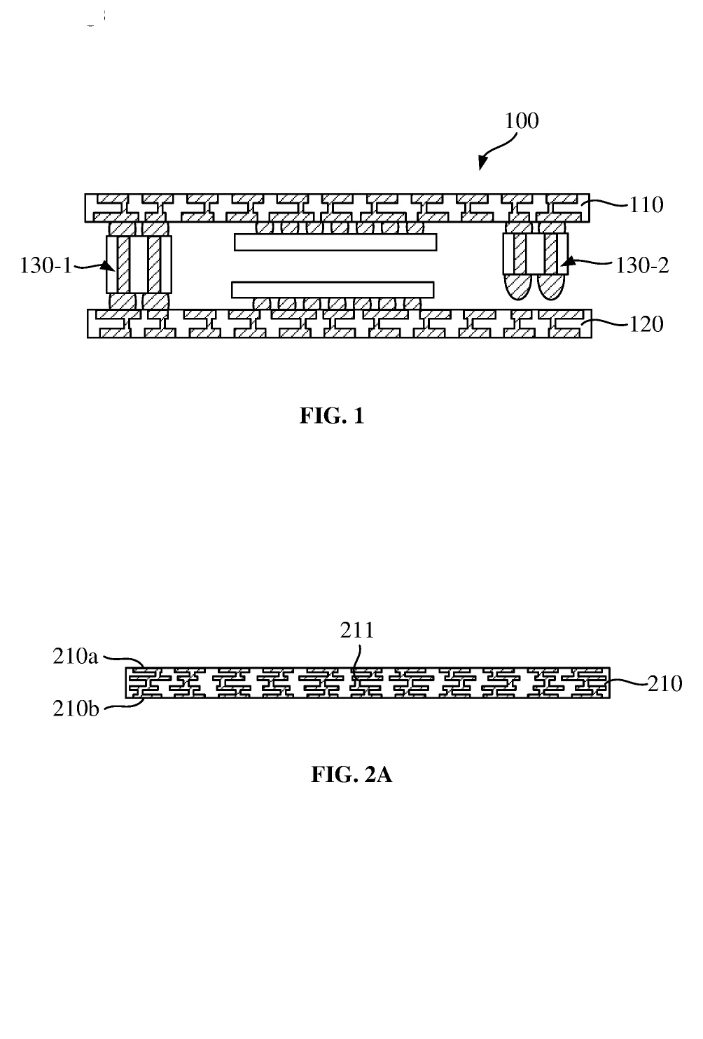

FIG. 1 illustrates a semiconductor package 100, in which preformed conductive blocks 130-1 and 130-2 are mounted on a first substrate 110 to couple with a second substrate 120. However, the inventors of the present application noticed that the semiconductor package 100 incorporating the conductive blocks 130-1 and 130-2 has a relatively lower yield and is low in reliability. After an investigation of samples of the semiconductor package 100, the inventors have identified that there may be a significant height difference between the conductive blocks 130-1 and 130-2 on the first substrate 110, due to a difference in the size and height of solder bumps for mounting the conductive blocks 130-1 and 130-2 onto the substrates 110 and 120. Consequently, when the second substrate 120 is mounted on the two conductive blocks 130-1 and 130-2, the height difference may lead to a tilted installation or even an open circuit, which reduces the reliability of the semiconductor package 100.

To address at least one of the above problems, a method for forming a semiconductor package is provided. In the method, a double-sided laser compression bonding process is used to alleviate height differences among different conductive blocks. Specifically, after the conductive blocks are disposed between a first substrate and a second substrate, solder bumps of the conductive blocks are irradiated from both the first substrate side and the second substrate side, and at the same time, the first substrate and the second substrate are pressed towards each other. The irradiation may heat and/or reflow the solder bumps and the pressure may adjust the size or height of the solder bumps, ensuring that the conductive blocks are reliably mounted between the first substrate and the second substrate.

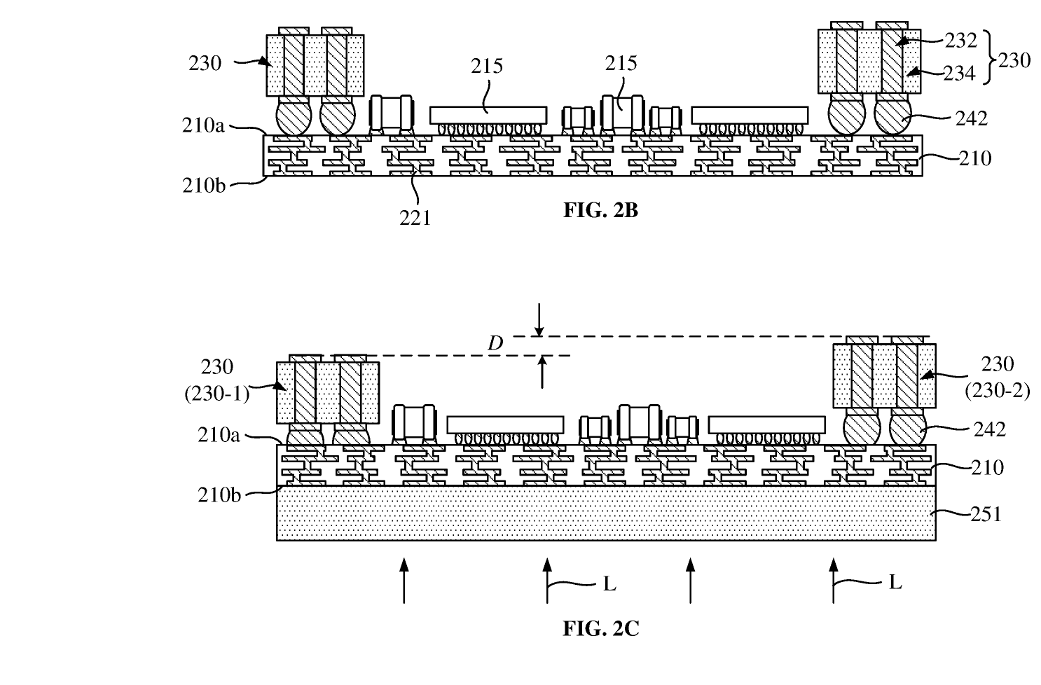

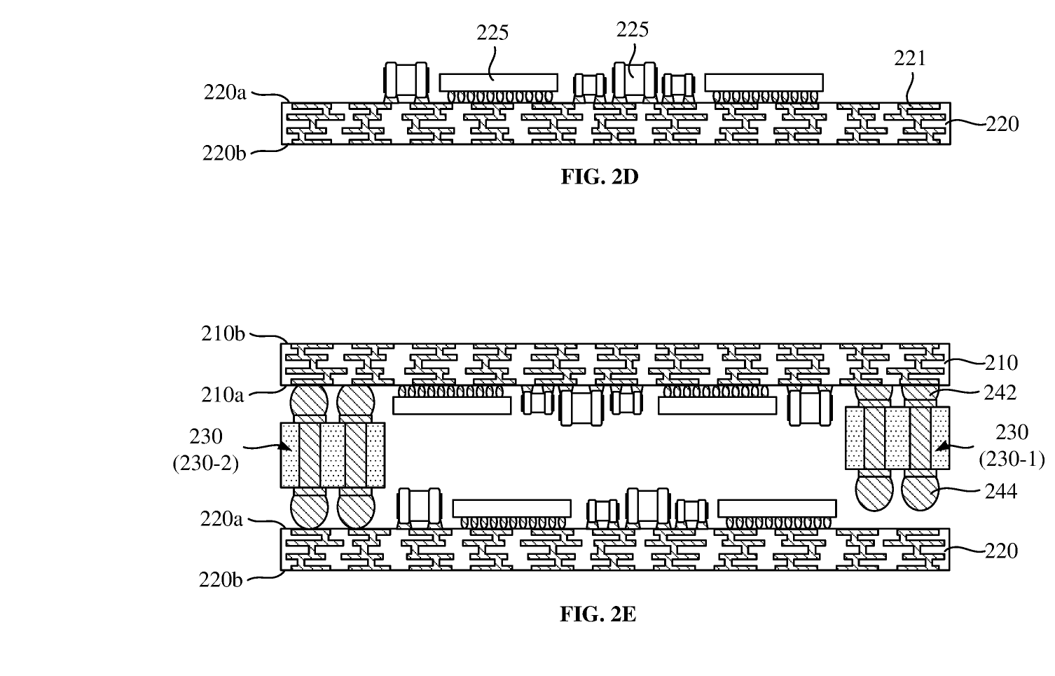

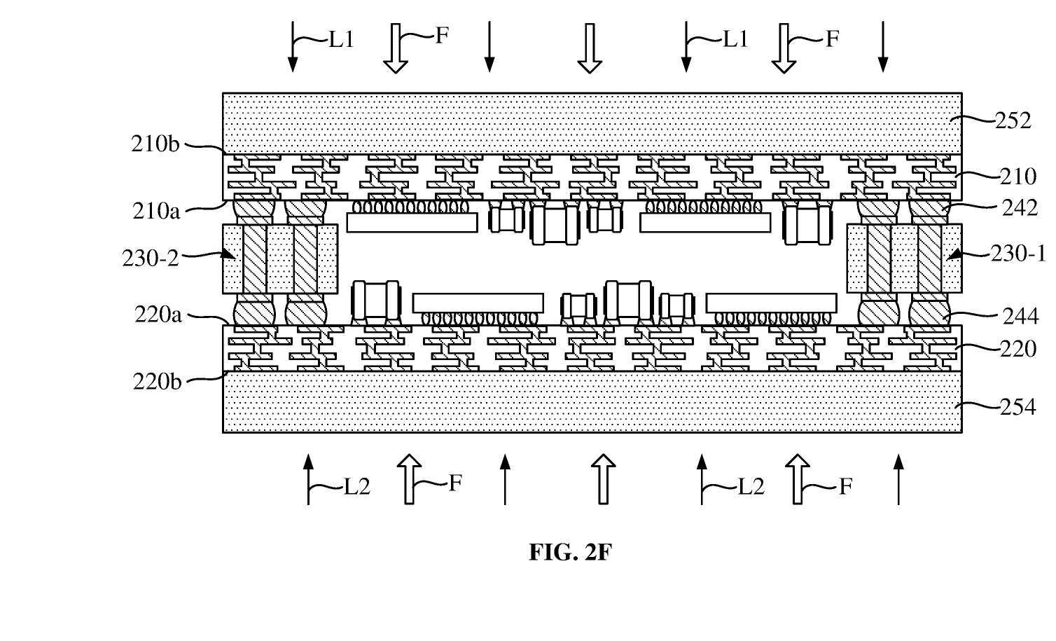

Referring to FIGS. 2A to 2F, various steps of a method for forming a semiconductor package are illustrated according to an embodiment of the present application. In the following, the method will be described with reference to FIGS. 2A to 2F in more details.

Referring to FIG. 2A, a first substrate 210 is provided. The first substrate 210 has a front surface 210a and a back surface 210b, and a plurality of interconnection structures 211 are formed in the first substrate 210. The front surface 210a of the first substrate 210 may serve as a platform where electronic components and conductive blocks can be mounted on, and the back surface 210b is opposite to the front surface 210a.

By way of example, the first substrate 210 may include a printed circuit board (PCB), a carrier substrate, a semiconductor substrate with electrical interconnections, or a ceramic substrate. However, the first substrate 210 is not limited to these examples. In other examples, the first substrate 210 may include a laminate interposer, a strip interposer, a leadframe, or other suitable substrates. In some embodiments, to enhance manufacturing throughput, the first substrate 210 may include a plurality of predefined substrate units arranged in a strip manner, thereby allowing some manufacturing processes to be performed on all the substrate units in parallel.

The interconnection structures 211 can provide connectivity for electronic components mounted on the first substrate 210. The interconnection structures 211 may define pads, traces and plugs through which electrical signals or voltages can be distributed horizontally and vertically across the first substrate 210. For example, the interconnection structures 211 may include a redistribution structure (RDS) having one or more dielectric layers and one or more conductive layers between and through the dielectric layers.

Referring to FIG. 2B, a plurality of conductive blocks 230 are disposed on the front surface 210a of the first substrate 210.

In some embodiments, a solder material may be deposited onto the contact pads on the front surface 210a of the first substrate 210 to form a first plurality of solder bumps 242, and the plurality of conductive blocks 230 are disposed on the front surface 210a of the first substrate 210 to contact with the first plurality of solder bumps 242. In some embodiments, the first plurality of solder bumps 242 may be formed on the plurality of conductive blocks 230, and the plurality of conductive blocks 230 are disposed with the first plurality of solder bumps 242 contacting with the contact pads on the front surface 210a of the first substrate 210. In some embodiments, the first plurality of solder bumps 242 may include eutectic Sn/Pb, high-lead solder, lead-free solder, or other suitable materials.

In some embodiments, the conductive blocks 230 may be preformed e-bar blocks that include built-in conductive pillars such as copper pillars and an insulative base material separating the copper pillars from each other. For example, as shown in FIG. 2B, each e-bar block 230 includes two conductive pillars 232 which are surrounded by a dielectric layer 234 such as an insulative polymeric material or composite. To be more specific, bottom surfaces of the conductive pillars 232 are exposed from a bottom surface of the dielectric layer 234 for contacting the first plurality of solder bumps 242. Similarly, top surfaces of the conductive pillars 232 are exposed from a top surface of the dielectric layer 234 for electrical contact purpose, for example, with an external device. In some embodiments, contact pads may be formed on two ends of each conductive pillar 232 for the convenience of contact. It could be understood that the number of the conductive pillars 232 included in each conductive block 230 may vary according to actual needs of the semiconductor package.

In some embodiments, as shown in FIG. 2B, at least one first electronic component 215 is also disposed on the front surface 210a of the first substrate 210. The first electronic component 215 may include any of a variety of types of semiconductor dice, semiconductor packages, or discrete devices. For example, the first electronic component 215 may include a logic chip such as a central processing unit (CPU) or a graphics processing unit (GPU), a memory device such as a high bandwidth memory (HBM), a digital signal processor (DSP), a radiofrequency (RF) circuit, a wireless baseband system-onchip (SoC) processor, a sensor, an application specific integrated circuit, etc. The first electronic component 215 may be passive components such as resistors, capacitors, inductors, switches, or any other suitable electronic devices.

In some embodiments, as shown in FIG. 2B, the conductive blocks 230 are thicker than the first electronic component 215. In other words, a top surface the first electronic component 215 may be lower than top surfaces of the conductive blocks 230. In this way, the semiconductor package can be electrically connected with other external electronic devices via the conductive blocks 230 while, at the same time, keeping the first electronic component 215 isolated from other devices. In some embodiments, the conductive blocks 230 and the first electronic component 215 can be disposed onto the front surface 210a of the first substrate 210 simultaneously, while in some other embodiments, the conductive blocks 230 may be attached onto the front surface 210a of the first substrate 210 before or after the first electronic component 215 is disposed.

Referring to FIG. 2C, the first plurality of solder bumps 242 are irradiated from the back surface 210b of the first substrate 210.

In some embodiments, as shown in FIG. 2C, the back surface 210b of the first substrate 210 may be attached on a transparent plate 251, which includes, for example, quartz or other transparent materials. Then, the transparent plate 251 is irradiated with a laser beam L, as indicated by arrows in FIG. 2C. For example, the laser beam L may be an infrared laser beam. The laser beam L can pass through the transparent plate 251 and the first substrate 210, and then heat and/or reflow the first plurality of solder bumps 242, so as to bond the conductive blocks 230 onto the front surface 210a of the first substrate 210. Compared with a conventional reflowing process, the laser beam can reduce thermal stress generated in the package with fast heating and cooling processes. Further, irradiating the first plurality of solder bumps 242 from the back surface 210b of the first substrate 210 can generate a uniform heat energy, as the back surface 210b of the first substrate 210 has a uniform structure. However, the present application is not limited thereto. In some other embodiments, the first plurality of solder bumps 242 can be bonded onto the front surface 210a of the first substrate 210 using other suitable surface mounting techniques.

In the example shown in FIG. 2C, the plurality of conductive blocks 230 includes a first conductive block 230-1 mounted on the left portion of the first substrate 210 and a second conductive block 230-2 mounted on the right portion of the first substrate 210. In some cases, the conductive blocks 230 at different positions on the first substrate 210 may have different heights due to, for example, the unevenness of the front surface 210a of the first substrate 210, the nonuniformity of the reflowing process of the first plurality of solder bumps 242 and/or the inconformity of the attaching process of the conductive blocks 230 onto the first substrate 210. For example, the heights of the solder bumps 242 under the first conductive block 230-1 may be different from the heights of the solder bumps 242 under the second conductive block 230-2, rendering a height difference “D” between the top surfaces of the first conductive block 230-1 and the second conductive block 230-2. Specifically, the top surface of the second conductive block 230-2 is higher than the top surface of the first conductive block 230-1, as shown in FIG. 2C.

Referring to FIG. 2D, a second substrate 220 is provided. The second substrate 220 has a front surface 220a and a back surface 220b, and a plurality of interconnection structures 221 are formed in the second substrate 220. The front surface 220a of the second substrate 220 may serve as a platform where electronic components and conductive devices can be mounted on, and the back surface 220b is opposite to the front surface 220a. The second substrate 220 may have a similar structure and configuration as the first substrate 210, and will not be elaborated herein.

In some embodiments, as shown in FIG. 2D, at least one second electronic component 225 is mounted on the front surface 220a of the second substrate 220 via, for example, solder bumps. The second electronic component 225 may include any of a variety of types of semiconductor dice, semiconductor packages, or discrete devices, and may be the same as or different from the first electronic component 215.

Referring to FIG. 2E, the second substrate 220 is disposed on the plurality of conductive blocks 230 via a second plurality of solder bumps 244, and the front surface 220a of the second substrate 220 faces the front surface 210a of the first substrate 210.

In some embodiments, the second plurality of solder bumps 244 are formed on the plurality of conductive blocks 230. Specifically, as shown in FIG. 2E, two solder bumps are formed on the first conductive block 230-1, and two solder bumps are formed on the second conductive block 230-2. As the top surfaces of the first conductive block 230-2 and the second conductive block 230-2 are at different heights, top surfaces of the solder bumps formed on the first conductive block 230-2 and the second conductive block 230-2 are still at different heights. Then, the first substrate 210 is flipped with its front surface 210a facing downward, and the first substrate 210 may be manipulated to contact the second plurality of solder bumps 244 with the front surface 220a of the second substrate 220.

However, the present application it not limited to the above embodiments. In some other embodiments, the second plurality of solder bumps 244 may be formed on the front surface 220a of the second substrate 220, and the first substrate 210 may be manipulated to contact the plurality of conductive blocks 230 with the second plurality of solder bumps 244 on the front surface 220a of the second substrate 220. In some other embodiments, the front surface 210a of the first substrate 210 faces upward, and the second substrate 220 may be flipped with its front surface 220a facing downward.

Next, referring to FIG. 2F, a double-sided laser compression bonding process is performed to alleviate height differences among the plurality of conductive blocks 230.

In some embodiments, a first transparent plate 252 is disposed on the back surface 210b of the first substrate 210, and a second transparent plate 254 is disposed on the back surface 220b of the second substrate 220. By way of example, the first transparent plate 252 and the second transparent plate 254 may include quartz or other transparent materials. Then, an external force F (as indicated by hollow arrows in FIG. 2F) may be evenly applied on the first transparent plate 252 and/or the second transparent plate 254 to press the first transparent plate 252 and the second transparent plate 254 towards each other. Accordingly, the first substrate 210 and the second substrate 220 are pressed towards each other. At the same time, the first transparent plate 252 is irradiated with a first laser beam L1, and the second transparent plate 254 is irradiated with a second laser beam L2. The first laser beam L1 can pass through the first transparent plate 252 and the first substrate 210 to irradiate the first plurality of solder bumps 242, and the second laser beam L2 can pass through the second transparent plate 254 and the second substrate 220 to irradiate the second plurality of solder bumps 244. The first laser beam L1 and the second laser beam L2 may be infrared laser beams, and can heat and/or reflow the first plurality of solder bumps 242 and the second plurality of solder bumps 244. As the first substrate 210 and the second substrate 220 are pressed towards each other by the external force F, the size or height of the first plurality of solder bumps 242 and the second plurality of solder bumps 244 may be adjusted to alleviate height differences among the plurality of conductive blocks 230, thereby ensuring that the plurality of conductive blocks 230 are reliably mounted between the first substrate 210 and the second substrate 220.

In some embodiments, a plurality of vacuum holes may be formed in the first transparent plate 252 and/or the second transparent plate 254, and a vacuum may be applied through the vacuum holes to maintain or force the first substrate 210 and/or the second substrate 220 against the first transparent plate 252 and/or the second transparent plate 254, so as to prevent warpage of the first substrate 210 and/or the second substrate 220 during the irradiating processes.

In some embodiments, a temperature of the first transparent plate 252 and/or the second transparent plate 254 is maintained at 70°C to 100°C during the irradiating, to prevent thermal shock of the solder bumps 242 and 244 from sudden temperature rise.

In some embodiments, the first plurality of solder bumps 242 and/or the second plurality of solder bumps 244 are irradiated with the first laser beam L1 and/or the second laser beam L2 for 2 seconds to 10 seconds (for example, 5 seconds), and are cooled down within 5 seconds to 20 seconds (for example, 10 seconds). The fast heating and cooling processes can reduce thermal stress generated in the semiconductor package.

In some embodiments, a molding material may be further formed between the front surface 210a of the first substrate 210 and the front surface 220a of the second substrate 220 to encapsulate the first electronic component 215, the second electronic component 225 and the conductive blocks 230. The molding material may include epoxy resin, epoxy resin with filler, epoxy acrylate with filler, or polymer with proper filler, but the scope of this application is not limited thereto. In some embodiments, the molding material may be formed by using compressive molding, transfer molding, liquid encapsulant molding, or other suitable molding processes.

In some embodiments, after removing the first transparent plate 252 and the second transparent plate 254, a plurality of solder bumps may be further formed on the back surface 220b of the second substrate 220 and/or the back surface 210b of the first substrate 210, and may be used for electrically connecting the semiconductor package to external devices or substrates.

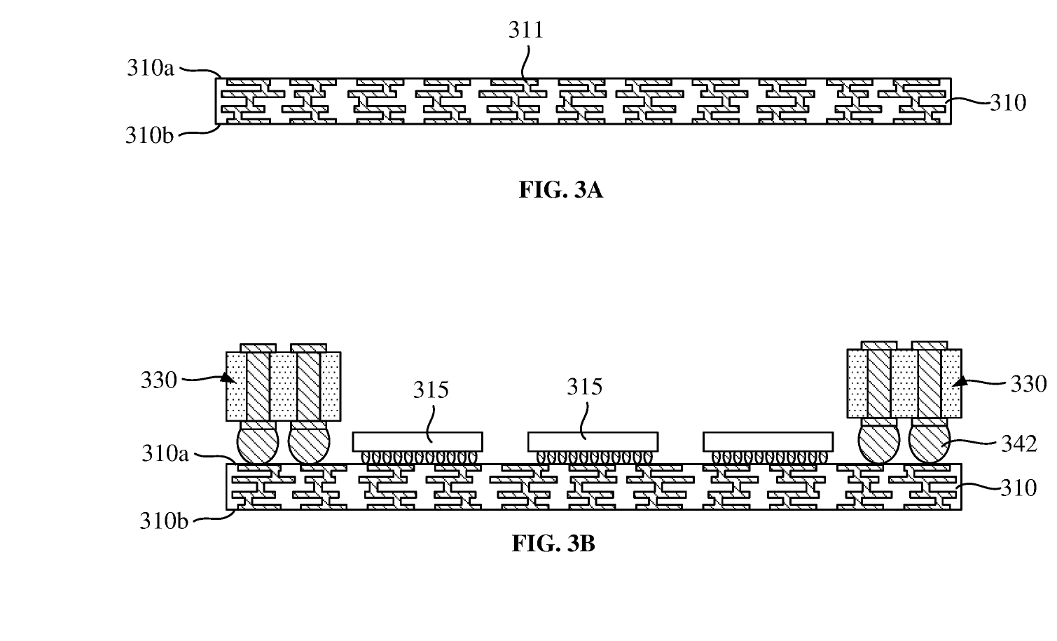

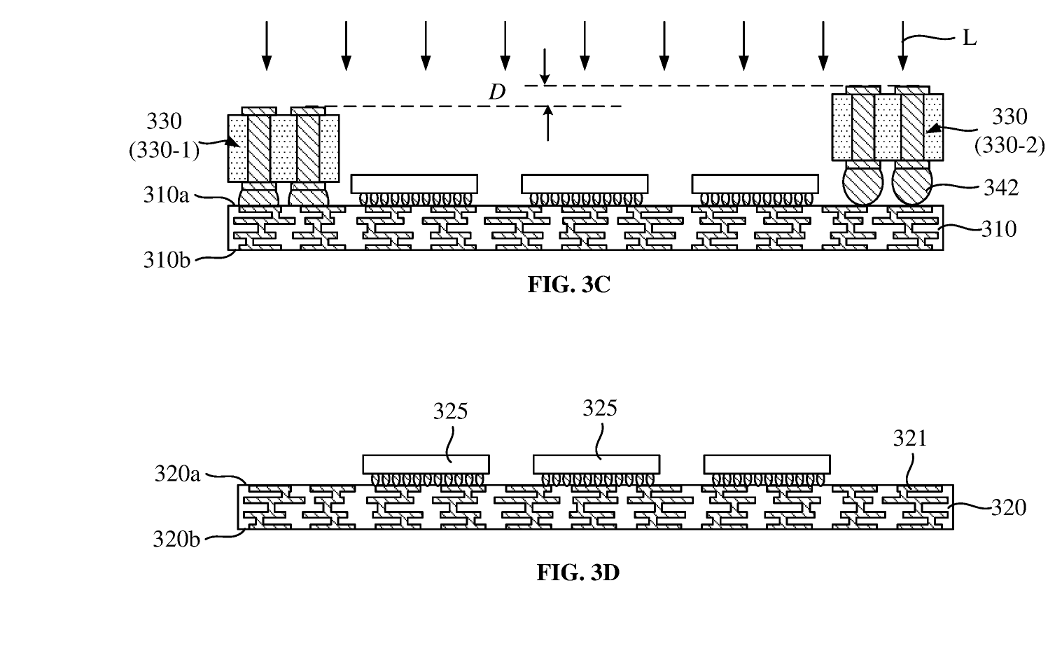

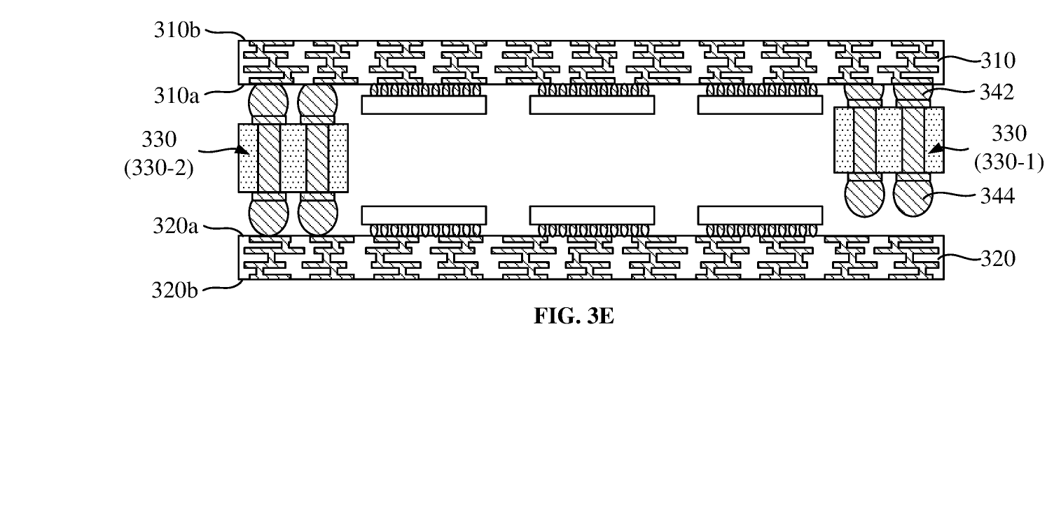

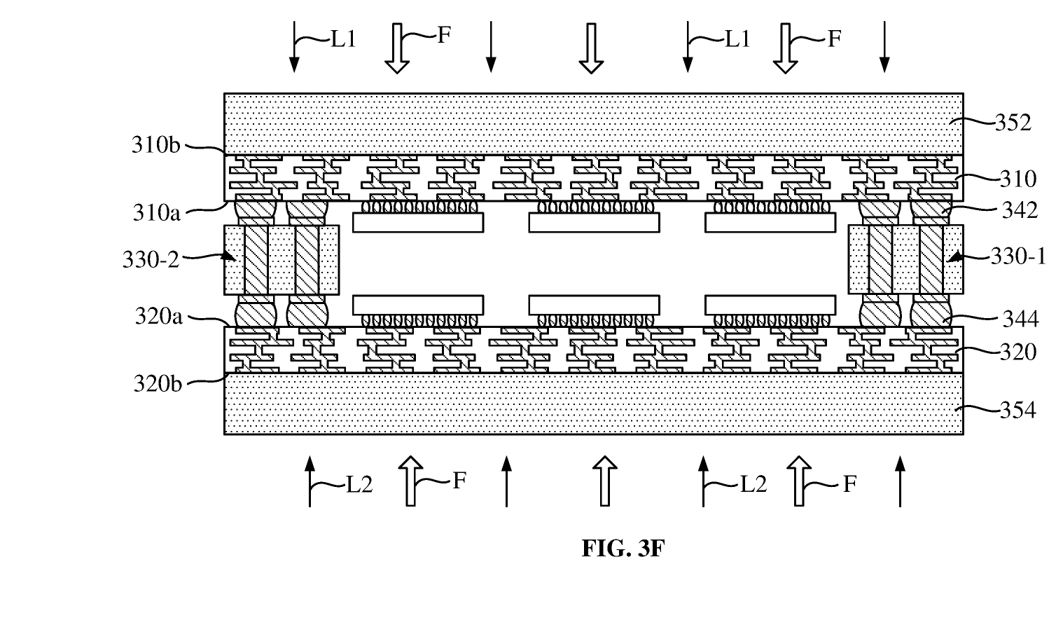

Referring to FIGS. 3A to 3F, various steps of a method for forming a semiconductor package are illustrated according to another embodiment of the present application. The method may have similar operations or configurations as the method described with reference to FIGS. 2A-2F, which will not be elaborated herein.

Referring to FIG. 3A, a first substrate 310 is provided. The first substrate 310 has a front surface 310a and a back surface 310b, and a plurality of interconnection structures 311 are formed in the first substrate 310. The front surface 310a of the first substrate 310 may serve as a platform where electronic components and conductive blocks can be mounted on, and the back surface 310b is opposite to the front surface 310a.

Next, referring to FIG. 3B, a plurality of conductive blocks 330 are disposed on the front surface 310a of the first substrate 310. In some embodiments, a solder material may be deposited onto contact pads on the front surface 310a of the first substrate 310 to form a first plurality of solder bumps 342, and the plurality of conductive blocks 330 are disposed on the front surface 310a of the first substrate 310 to contact with the first plurality of solder bumps 342. In some embodiments, the conductive blocks 330 may be preformed e-bar blocks that include built-in conductive pillars such as copper pillars and an insulative base material separating the copper pillars from each other. In some embodiments, as shown in FIG. 3B, at least one first electronic component 315 is also disposed on the front surface 310a of the first substrate 310. The first electronic component 315 may include any of a variety of types of semiconductor dice, semiconductor packages, or discrete devices.

Referring to FIG. 3C, the first plurality of solder bumps 342 are irradiated from the front surface 310a of the first substrate 310.

Specifically, the front surface 310a of the first substrate 310 may be irradiated with a laser beam L, as indicated by arrows in FIG. 3C. The laser beam L can pass through the conductive blocks 330 and reflow the first plurality of solder bumps 342. For example, a laser-assisted bonding (LAB) technique may be used to implement the laser irradiation. LAB is an advanced flip chip and surface mount bonding technology in which a homogenized laser beam (that is, a two-dimensional beam, not a one-dimensional beam) is selectively applied to a chip or component in order to establish a metallurgical interconnection with the substrate.

In some cases, the conductive blocks 330 at different positions on the first substrate 310 may have different heights due to, for example, the unevenness of the front surface 310a of the first substrate 310, the nonuniformity of the reflowing process of the first plurality of solder bumps 342 and/or the inconformity of the attaching process of the conductive blocks 330 onto the first substrate 310. For example, the heights of the solder bumps 342 under a first conductive block 330-1 may be different from the heights of the solder bumps 342 under a second conductive block 330-2, rendering a height difference “D” between the top surfaces of the first conductive block 330-1 and the second conductive block 330-2.

Referring to FIG. 3D, a second substrate 320 is provided. The second substrate 320 has a front surface 320a and a back surface 320b, and a plurality of interconnection structures 321 are formed in the second substrate 320. At least one second electronic component 325 is mounted on the front surface 320a of the second substrate 320 via, for example, solder bumps. The second electronic component 325 may include any of a variety of types of semiconductor dice, semiconductor packages, or discrete devices, and may be the same as or different from the first electronic component 315.

Referring to FIG. 3E, the second substrate 320 is disposed on the plurality of conductive blocks 330 via a second plurality of solder bumps 344, and the front surface 320a of the second substrate 320 faces the front surface 310a of the first substrate 310. For example, the second plurality of solder bumps 344 are formed on the plurality of conductive blocks 330. Then, the first substrate 310 is flipped with its front surface 310a facing downward, and the first substrate 310 may be manipulated to contact the second plurality of solder bumps 344 with the front surface 320a of the second substrate 320.

Referring to FIG. 3F, a double-sided laser compression bonding process is performed to alleviate height differences among the plurality of conductive blocks 330.

In some embodiments, a first transparent plate 352 is disposed on the back surface 310b of the first substrate 310, and a second transparent plate 354 is disposed on the back surface 320b of the second substrate 320. Then, an external force F (as indicated by hollow arrows in FIG. 3F) may be evenly applied on the first transparent plate 352 and/or the second transparent plate 354 to press the first transparent plate 352 and the second transparent plate 354 towards each other. Accordingly, the first substrate 310 and the second substrate 320 are pressed towards each other. At the same time, the first transparent plate 352 is irradiated with a first laser beam L1, and the second transparent plate 354 is irradiated with a second laser beam L2. The first laser beam L1 and the second laser beam L2 can heat and/or reflow the first plurality of solder bumps 342 and the second plurality of solder bumps 344. As the first substrate 310 and the second substrate 320 are pressed towards each other by the external force F, the size or height of the first plurality of solder bumps 342 and the second plurality of solder bumps 344 may be adjusted to alleviate height differences among the plurality of conductive blocks 330, thereby ensuring that the plurality of conductive blocks 330 are reliably mounted between the first substrate 310 and the second substrate 320.

According to another aspect of the present application, a semiconductor package made by the methods described above is provided. The details of the semiconductor package may refer to the methods described above, and are not elaborated herein.

The discussion herein included numerous illustrative figures that showed various portions of a semiconductor package and a method for making the same. For illustrative clarity, such figures did not show all aspects of each exemplary semiconductor package. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a first substrate having a first front surface and a first back surface;
mounting a plurality of conductive blocks on the first front surface of the first substrate via a first plurality of solder bumps;
providing a second substrate having a second front surface and a second back surface;
disposing the second substrate on the plurality of conductive blocks via a second plurality of solder bumps, wherein the second front surface of the second substrate faces the first front surface of the first substrate;
pressing the first substrate and the second substrate towards each other; and
irradiating the first plurality of solder bumps and the second plurality of solder bumps from the first back surface of the first substrate and the second back surface of the second substrate, respectively.

2. The method of claim 1, wherein mounting the plurality of conductive blocks on the first front surface of the first substrate via the first plurality of solder bumps comprises:
irradiating the first plurality of solder bumps from the first back surface of the first substrate.

3. The method of claim 1, wherein mounting the plurality of conductive blocks on the first front surface of the first substrate via the first plurality of solder bumps comprises:
irradiating the first plurality of solder bumps from the first front surface of the first substrate.

4. The method of claim 1, wherein pressing the first substrate and the second substrate towards each other comprises:
disposing a first transparent plate on the first back surface of the first substrate;
disposing a second transparent plate on the second back surface of the second substrate; and
pressing the first transparent plate and the second transparent plate towards each other.

5. The method of claim 4, wherein irradiating the first plurality of solder bumps and the second plurality of solder bumps from the first back surface of the first substrate and the second back surface of the second substrate respectively comprises:
irradiating the first plurality of solder bumps with a first laser beam, wherein the first laser beam passes through the first transparent plate and the first substrate; and
irradiating the second plurality of solder bumps with a second laser beam, wherein the second laser beam passes through the second transparent plate and the second substrate.

6. The method of claim 5, wherein first transparent plate and the second transparent plate comprise quartz.

7. The method of claim 5, wherein the first laser beam and the second laser beam comprise an infrared laser beam.

8. The method of claim 5, wherein a temperature of the first transparent plate and/or the second transparent plate is maintained at 70°C to 100°C during the irradiating.

9. The method of claim 5, wherein a plurality of vacuum holes are formed in each of the first transparent plate and the second transparent plate.

10. The method of claim 5, wherein the first plurality of solder bumps are irradiated with the first laser beam for 2 seconds to 10 seconds, and the second plurality of solder bumps are irradiated with the second laser beam for 2 seconds to 10 seconds.

11. The method of claim 1, wherein the plurality of conductive blocks comprises preformed e-bar blocks.

12. The method of claim 1, further comprising:
mounting at least one first electronic component on the first front surface of the first substrate; and
mounting at least one second electronic component on the second front surface of the second substrate.

13. A semiconductor package, wherein the semiconductor package is formed using the method of claim 1.
